(19) United States
(12) Patent Application Publication
(10) Pub. No.: US 2014/0046089 A1
(43) Pub. Date: Feb. 13, 2014

(54) CONTINUOUS PROCESS FOR THE FUNCTIONALIZATION OF FULLERENES

(71) Applicants: David Jones, Melbourne (AU); Wing Ho Wallace Wong, Carlton (AU); Andrew Holmes, Melbourne (AU); Helga Seyler, Melbourne (AU)

(72) Inventors: David Jones, Melbourne (AU); Wing Ho Wallace Wong, Carlton (AU); Andrew Holmes, Melbourne (AU); Helga Seyler, Melbourne (AU)

(73) Assignee: The University of Melbourne, Parkville, VC (AU)

(21) Appl. No.: 13/997,132

(22) PCT Filed: Dec. 21, 2011
(86) PCT No.: PCT/AU2011/001649

§ 371 Date: Sep. 23, 2013

(30) Foreign Application Priority Data
Dec. 23, 2010 (AU) 2010905624

(51) Int. Cl. H01L 51/00

(52) U.S. Cl. CPC H01L 51/0047; H01L 51/0049
USPC 560/103; 585/425; 585/27

(57) ABSTRACT

A continuous process for the functionalization of fullerenes is disclosed. The process offers numerous advantages in comparison to traditional batch processes. The functionalized fullerenes may find use in the fabrication of hetero-junction devices.

### FIELD OF THE INVENTION

The present invention relates to a continuous process for the functionalization of fullerenes and carbon nanotubes and to functionalized derivatives produced therefrom. Such functionalized derivatives find particular, although not exclusive, use as organic semiconductor materials.

### BACKGROUND TO THE INVENTION

The fundamental fullerene architecture is composed entirely of carbon, in the form of a hollow sphere, ellipsoid, or tube. Spherical fullerenes are also known as buckyballs, and cylindrical fullerenes are called carbon nanotubes or buckytubes.

Fullerene is one of the most widely studied class of n-type organic semiconductor materials. Buckminsterfullerene (C₆₀) can reversibly uptake six electrons and electron mobility in the order of 1 cm²/Vs has been measured [Haddon, R. C.; Perel, A. S.; Morris, R. C.; Palstra, T. T. M.; Hebard, A. F.; Fleming, R. M. Appl. Phys. Lett. 1995, 67, 121-123; Kobayashi, S.; Takenobu, T.; Mori, S.; Fujiwara, A.; Iwasa, Y. Appl. Phys. Lett. 2003, 82, 4581-4583; Singh, T. B.; Marjanovic, N.; Matt, G. J.; Gunes, S.; Sariciftci, N. S.; Ramil, A. M.; Andreev, A.; Sitter, H.; Schwodiauer, R.; Bauer, S. Org. Electron. 2005, 6, 105-110; Anthopoulos, T. D.; Singh, B.; Marjanovic, N.; Sariciftci, N. S.; Ramil, A. M.; Sitter, H.; Cölle, M.; de Leeuw, D. M. Appl. Phys. Lett. 2006, 89, 213504; Singh, T. B.; Sariciftci, N. S.; Yang, H.; Yang, L.; Plochberger, B.; Sitter, H. Appl. Phys. Lett. 2007, 90, 213512; MacKenzie, R. C. I.; Frost, J. M.; Nelson, J. J. Chem. Phys. 2010, 132, 064904].

Functionalized derivatives of fullerenes (C₆₀ and C₇₀) have been used extensively in donor-acceptor bulk heterojunction (BHJ) solar cells due to their remarkable electronic properties and solution processability [Günes, S.; Neugebauer, H.; Sariciftci, N. S. Chem. Rev. 2007, 107, 1324-1338; Lloyd, M. T.; Anthony, J. E.; Malliaras, G. G. Mater. Today 2007, 10, 34-41; Dennler, G.; Scharber, M. C.; Brabec, C. J. Adv. Mater. 2009, 21, 1323-1338: Brabec, C. J.; Gowrisanker, S.; Halls, J. J. M.; Laird, D.; Jia, S.; Williams, S. P. Adv. Mater. 2010, 22, 3839-3856; Hains, A. W.; Liang, Z.; Woodhouse, M. A.; Gregg, B. A. Chem. Rev. 2010, DOI: 10.1021/cr9002984; Inganäs, O.; Zhang, F.; Tvingstedt, K.; Andersson, L. M.; Hellström, S.; Andersson, M. R. Adv. Mater. 2010, 22, E100-E116].

State-of-the-art BHJ devices typically consist of a polymeric donor material and fullerene derivatives as acceptors [Liang, Y. Y.; Xu, Z.; Xia, J. B.; Tsai, S. T.; Wu, Y.; Li, G.; Ray, C.; Yu, L. P. Adv. Mater. 2010, 22, E135; Chen, H. -Y.; Hou, J.; Zhang, S.; Liang, Y.; Yang, G.; Yang, Y.; Yu, L.; Wu, Y.; Li, G. Nat. Photon 2009, 3, 649-653].

One of the main advantages of BHJ solar cells is the possibility of cheap and fast device fabrication by employing reel-to-reel printing techniques. However, a large quantity of material is required to optimize the performance of printed devices.

There are numerous methods available for the functionalization of fullerenes. Exemplary reactions include cyclopropanations, 1,3-dipolar cycloadditions and Diels-Alder cycloadditions [Suzuki, T.; Li, Q.; Khemani, K. C.; Wudl, F., J. Am. Chem. Soc. 1992, 114, 7301; Taylor, R.; Walton, D. R. M., Nature 1993, 363, 685; Hirsch, A., Synthesis-Stuttgart 1995, 895; Diederich, F.; Thilgen, C., Science 1996, 271, 317; Puplovskis, A.; Kacens, J.; Neilands, O., Tetrahedron Lett. 1997, 38, 285].

While these are relatively simple single-step reactions, the reaction scale is seriously restricted by the amount of solvent required to fully dissolve the fullerene starting material. The solubility of C₆₀ in toluene is only 2.8 mg/mL at 25° C. [Ruoff, R. S.; Tse, D. S.; Malhotra, R.; Lorents, D. C., J. Phys. Chem. 1993, 97, 3379].

Accordingly, it would be desirable to provide a method of fullerene and carbon nanotube functionalization that addresses the scalability restrictions and that is also straightforward to implement.

### SUMMARY OF THE INVENTION

According to a first aspect of the present invention there is provided a continuous process for the functionalization of fullerenes or carbon nanotubes comprising one or more process steps wherein at least one process step is conducted at a temperature above 25° C.

According to a second aspect of the present invention there is provided a continuous process for the functionalization of fullerenes or carbon nanotubes comprising one or more process steps wherein the process steps are conducted substantially in the liquid phase.

Advantageously, according to an embodiment of this aspect of the present invention all process steps are conducted under homogeneous conditions, in the absence of solid phase reagents.

The advantages of the processes of the present invention may include, most importantly, scalability and a significant reduction in reaction time in comparison to traditional processes based on batch reactions or low temperature. Further advantages may include superior heat transfer and reagent control, a closed and fully contained reactor system allowing for safe handling of hazardous reagents and high pressure reactions and excellent reproducibility owing to precise control of parameters.

Exemplary, but non-limiting, functionalization reactions according to any one of the aforementioned aspects of the present invention may be selected from the group consisting of cyclopropanations, cycloadditions such as 1,3-dipolar cycloadditions and Diels-Alder [2+4] cycloadditions, organometallic additions such as Grignard additions, or combinations thereof. Grignard addition products may be subsequently alkylated.

In one embodiment the process according to any one of the aforementioned aspects of the present invention may be operated under conditions so as to improve the solubility of otherwise poorly soluble components. Such conditions may involve the use of varying reaction temperatures and/or pressures for single or multiple reaction steps. This is particularly useful in respect of fullerenes or carbon nanotubes where low solubility can often be problematic under traditional batch reaction conditions.

In an additional and advantageous embodiment, by using relatively low concentrations of components in the reactor(s), their reactivity may be controlled.

In a further embodiment the process according to any one of the aforementioned aspects of the present invention may be automated using process control systems, for example, through control of pressure and/or temperature. This is advantageous in respect of improved safety, particularly in avoiding potentially explosive situations.

In one embodiment the process according to any one of the aforementioned aspects of the present invention comprises at least two reaction steps performed at different reaction temperatures.

In an alternative or additional embodiment the process according to any one of the aforementioned aspects of the present invention comprises at least one thermal or photochemical isomerisation.

In a further alternative or additional embodiment the process according to any one of the aforementioned aspects of the present invention may be conducted utilising a stock solution wherein two or more reactants are premixed in a solvent and are subsequently introduced into one or more reactors of the process as a mixture.

Preferably the stock solution is prepared in one or more aprotic hydrocarbon solvents. Particularly preferred solvents are of an aromatic nature and/or of high boiling point.

In a preferred embodiment the process according to any one of the aforementioned aspects of the present invention comprises the functionalization of fullerene or carbon nanotubes or derivatives thereof with in situ generated diazo compounds from diazoalkane precursors and a soluble base. Preferably, an excess of base relative to the amount of diazoalkane precursor is utilised.

In a particularly preferred embodiment the diazoalkane precursor may be any compound known to give diazomethanes of the formula C(R₁R₂)N₂ via alkaline treatment, such as sulfonylhydrazones, N-alkyl-N-nitroso sulfonamides, carboxamides, urea and urethanes. A very preferred precursor is a tosylhydrazone.

In a further preferred embodiment the base is a soluble cyclic or linear organic base, preferably but not limited to 2,2,6,6-tetramethylpiperidine (TMP). Other soluble organic bases may be employed, which are suitable for deprotonation of the tosylhydrazone or for nucleophilic attack to the N-carbonyl or N-sulphonyl. This includes other cyclic and/or hindered amine derivatives such as N,N-diisopropylethylamine, pyrrolidine and other piperidine derivatives.

In a further preferred embodiment the process according to any one of the aforementioned aspects of the present invention comprises the functionalization of fullerene or carbon nanotubes or derivatives thereof by a Diels-Alder [2+4] cycloaddition wherein the process utilises an excess of diene relative to dieneophile.

In a yet further embodiment the process according to any one of the aforementioned aspects of the present invention may comprise one or more steps performed under superheated conditions. This is particularly advantageous in respect of conducting Diels Alder reactions.

According to a third aspect of the present invention there is provided a functionalized fullerene or carbon nanotube prepared by the process according to any one of the aforementioned aspects of the invention.

According to a fourth aspect of the present invention there is provided a use of the functionalized fullerene or carbon nanotube prepared by the process according to any one of the aforementioned aspects of the invention in a hetero-junction device.

According to a fifth aspect of the present invention there is provided a hetero-junction device comprising one or more functionalized fullerenes and/or nanotubes prepared by the process according to any one of the aforementioned aspects of the invention.

Throughout this specification, use of the terms “comprises” or “comprising” or grammatical variations thereon shall be taken to specify the presence of stated features, integers, steps or components but does not preclude the presence or addition of one or more other features, integers, steps, components or groups thereof not specifically mentioned.

### BRIEF DESCRIPTION OF THE FIGURES

The present invention will now be described with reference to the accompanying Figures where:

FIG. 1 illustrates a general scheme for the reaction setup: A), B) 1,3 dipolar and C) Diels-Alder cycloaddition.

FIG. 2 illustrates general flow reactor configurations namely a reaction setup for the A) small scale optimization and B) large scale fullerene functionalization via 1,3-dipolar cycloaddition.

FIG. 3 illustrates the synthesis of indene-C₆₀ bisadduct (IC₆₀BA) and indene-C₇₀ bisadduct (IC₇₀BA) under A) conventional batch reaction and B) continuous flow conditions.

### DETAILED DESCRIPTION OF THE INVENTION

It will now be convenient to describe the invention with reference to particular embodiments and examples. These embodiments and examples are illustrative only and should not be construed as limiting upon the scope of the invention. It will be understood that variations upon the described invention as would be apparent to the skilled artisan are within the scope of the invention. Similarly, the present invention is capable of finding application in areas that are not explicitly recited in this document and the fact that some applications are not specifically described should not be considered as a limitation on the overall applicability of the invention.

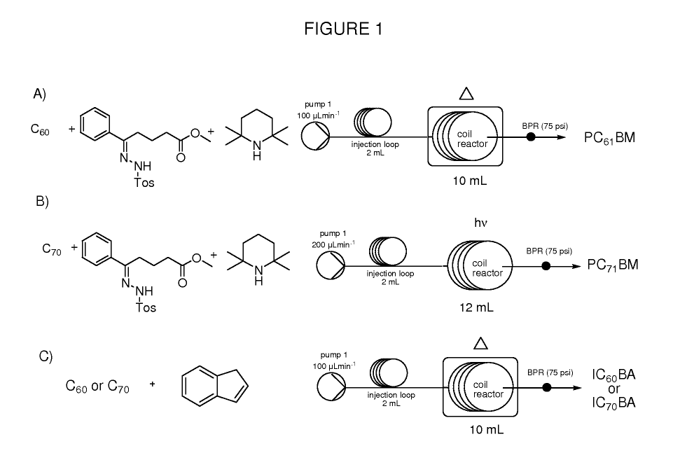

FIG. 1 provides an overview of the reaction set-ups for 1,3dipolar and Diels-Alder cycloadditions.

### General Conditions

The process reaction conditions may be appropriately varied and are dependent on the nature of the chemical reaction in question. Reaction pressures may range from 40 to 600 psi. Preferably reaction pressures are below 250 psi. The reactor residence time may vary, again depending on the specific chemistry, reagent stoichiometry and temperature. Residence times may be in the range of 0.1 and 10 hours, preferably in the range of 0.25 to 4 hours, more preferably in the range of 0.5 to 2 hours.

The continuous processes of the present invention may comprise a single reaction step or multiple reaction steps. In the latter case different temperatures or irradiation may be applied at individual process sections to promote or accelerate intermediate steps.

The continuous processes of the present invention may be performed in one or more tubular reactors or one or more continuous stirred tank reactors or combinations of both. The reactors may be arranged in series or in parallel depending on the specific nature of the chemical steps and the target product mix.

### 1,3-Dipolar Cycloadditions

Two of the most widely used fullerene derivatives in organic electronics are phenyl-C₆₁-butyric acid methyl ester (PC₆₁BM) and its C₇₀ analogue (PC₇₁BM). The synthesis of PC₆₁ BM is essentially a one-pot reaction with three steps [Hummelen, J. C.; Knight, B. W.; LePeq, F.; Wudl, F.; Yao, J.; Wilkins, C. L. J. Org. Chem. 1995, 60, 532-538; Mayorova, J. Y.; Nikitenko, S. L.; Troshin, P. A.; Peregudova, S. M.; Peregudov, A. S.; Kaplunov, M. G.; Lyubovskaya, R. N. Mendeleev Commun. 2007, 17, 175-177]. In the first step, the diazo intermediate is generated by the reaction of the tosylhydrazone precursor with sodium methoxide [Bamford, W. R., Stevens, T. S. J. Chem. Soc. 1952, 4735] in the presence of pyridine. 1,3-Dipolar cycloaddition of the diazo intermediate to the C₆₀ followed by N₂ liberation gives a mixture of two isomers of PC₆₁BM, the open-cage [5,6] fulleroid and close-cage [6,6]isomer. The mixture can then be thermally isomerized to give exclusively the desired close-cage [6,6]isomer.

While this reaction is relatively simple to perform in conventional batch reaction conditions, there are several problems to overcome if the reaction is to be successfully translated to continuous process methods. The primary challenges are the solubility of reactants and products. It would also be advantageous to use reagents that are less sensitive to oxygen and water.

### Functionalization of C60-Fullerenes

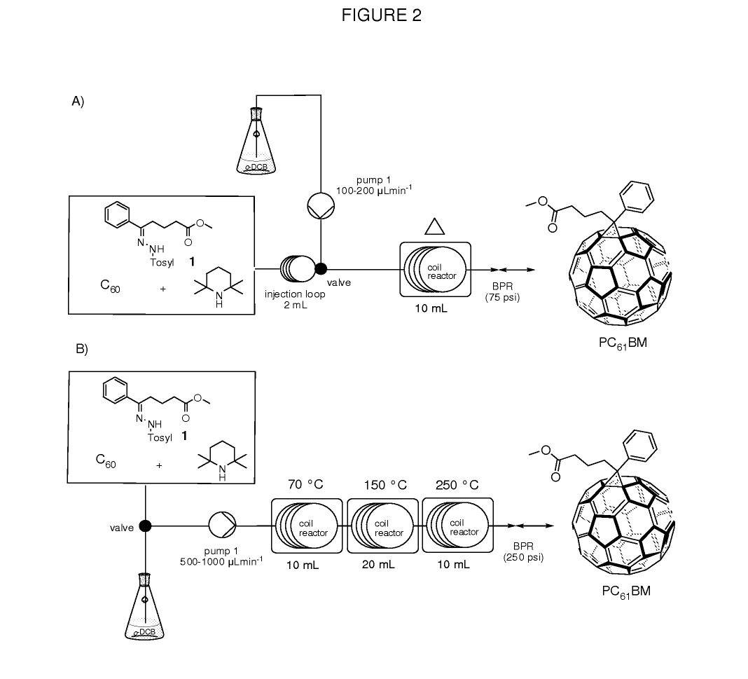

Electron acceptor phenyl-C₆₁-butyric acid methyl ester (PC₆₁BM) was synthesized using a continuous process (see FIGS. 2, A and B). The soluble C₆₀ fullerene derivative was functionalized via 1,3 dipolar cycloaddition with p-tosylhydrazone of methyl benzoylbutyrate as diazoalkane precursor. The optimization parameters were varied in terms of residence times, temperatures and equivalents of tosylhydrazone, thereby translating to variations in yield and nature of by-products (see Table 1).

Excellent results were obtained using stoichiometric quantities of tosylhydrazone 1 at high reaction temperatures, translating the low yielding overnight prior art batch reaction into moderate yields and direct thermolysis to the [6,6] isomer within 100 min (Table 1, entry 4).

The large scale continuous synthesis of PC₆₁ BM was performed with a reactor setup to allow a continuous feed of reactants from a stock solution reservoir (FIG. 2, B). It is important to note that the anomalous solubility behavior of C₆₀ must be taken into account in large scale continuous reactions. [Ruoff, R. S.; Malhotra, R.; Huestis, D. L.; Tse, D. S.; Lorents, D. C. Nature 1993, 362, 140-141] The fact that the solubility of C₆₀ decreases (by as much as ⅔) with increasing temperature can have significant impact on the progress of the reaction. As the stock solutions were prepared with near saturated room temperature concentrations of C₆₀ (28 mM), precipitation of C₆₀ in the tube reactor at temperature exceeding 150° C. is likely. To overcome this solubility problem, the reaction temperature was increased gradually from 70° C. (10 mL internal volume reator) to 150° C. (20 mL internal volume reactor) and 250° C. (10 mL reaction volume reactor). The temperature of the final coil reactor portion was raised to 250° C., ensuring complete isomerization from the [5,6] isomer to the [6,6] isomer. Additionally, the reduction of the residence time from 100 min (Table 1, entry 4) to 80 min and 40 min yielded 48% and 39% conversion respectively. Reducing the reaction time to less than one hour compromises the reaction yield by 20%, while increasing the throughput by 2.5 times.

An excess of base with respect to the diazo precursor may be preferred, typically between 2-10 equivalents and may vary depending on its reactivity. Typically 5 equivalents show good results. One equivalent of diazo precursor based on the fullerene is preferably used for monofunctionalization of the dipolarophile, although the amount may be increased if multiple functionalization is desired.

### Diels-Alder Cycloaddition ([2+4] Cycloaddition)

Diels-Alder adducts of indene with fullerenes have been successfully used to improve polymer/fullerene bulk heterojunction (BHJ) solar cell device performance. Both indene-C₆₀ bisadduct 9 (IC₆₀BA) and indene-C₇₀ bisadduct 10 (IC₇₀BA) are attractive fullerene acceptor materials for two main reasons.

Firstly, the lowest unoccupied molecular orbital (LUMO) energy levels of IC₆₀BA and IC₇₀BA are elevated compared with their PCBM counterparts leading to a larger open circuit voltage in BHJ devices with donor polymers.

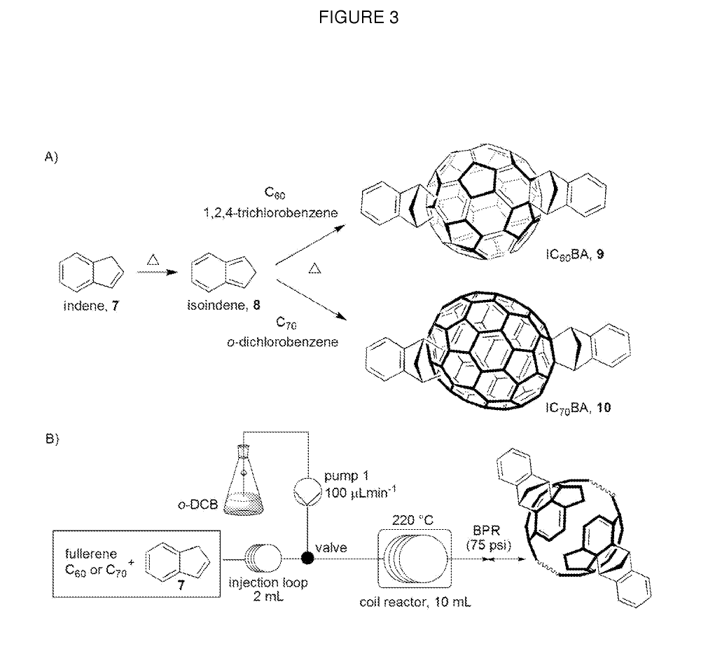

Secondly, the synthesis involves only two reactants; the Diels-Alder cycloaddition of indene and fullerene (FIG. 3, A). By using 1,2,4-trichlorobenzene as solvent, the yield of the reported batch reaction is 34% for IC₆₀BA [He, Y. J.; Chen, H. Y.; Hou, J. H.; Li, Y. F., J. Am. Chem. Soc. 2010, 132, 1377]. For IC₇₀BA, a high molar ratio of indene to C₇₀ in combination with long reaction times were shown to be necessary for good conversions (58%) [He, Y.; Zhao, G.; Peng, B.; Li, Y., Adv. Funct. Mater. 2010, 20, 3383]. It is important to note that both bisadducts of C₆₀ and C₇₀ consist of complex mixtures of regioisomers as can be observed by HPLC analyses.

One of the advantageous features of continuous reactions is the ability to perform reactions under pressure with superheated solvents. This means the high temperatures required for the Diels-Alder addition of indene to fullerenes should translate well to continuous methods. Indene is thermally converted to isoindene in a tube reactor, which then reacts with C₆₀ or C₇₀ via Diels-Alder cycloaddition (FIG. 3, B). The experiments were conducted with 20 to 36 equivalents of the indene under superheated conditions at 220° C. in a stainless steel reactor with o-DCB as a solvent. IC₆₀BA and IC₇₀BA were both successfully prepared in less than 2 h in 54% and 49% yield, respectively (Table1, entry 7) achieving comparable to significantly improved yields over the batch process.

TABLE 1
Optimization for the cycloadditions of C₆₀ and C₇₀ with diazo intermediate
4 and with indene under continuous process conditions

| | | | Diene/dipole | | Residence time | | | | Converted |
|---|---|---|---|---|---|---|---|---|---|
| | | | precursor | Conditions ^{[b]} | (min) [Prior | | Yield (%) ^{[c]} | | fullerenes |
| Entry | Fullerene | Reagent | (equiv.) | (° C.) | art, h] | | ^{[}Prior Art] | | (%) |
| 1 | C₆₀ | 1 ^{[a]} | 2 | 130 | 100 | | 45 | | 47 |
| 2 | C₆₀ | 1 ^{[a]} | 2 | 150 | 50 | | 42 | | 45 |
| 3 | C₆₀ | 1 ^{[a]} | 1 | 150 | 50 | | 53 | | 80 |
| 4 | C₆₀ | 1 ^{[a]} | 1 | 180 | 100 | [24-29^{d}] | 59 | [35^{d, e}] | 94 |
| 5 | C₆₀ | 1 ^{[a]} | 2 | hv | 60 | | 42 | | 45 |
| 6 | C₆₀ | 1 ^{[a]} | 1 | hv | 60 | | 49 | [59 ^{e, f}] | 94 |
| 7 | C₆₀ | Indene | 20 | 220 | 100 | [12^{g}] | 54 | [34^{g}] | 56 |
| 8 | C₆₀ | Indene | 36 | 220 | 100 | [12-72^{h}] | 49 | [8-58^{h}] | 52 |

^{[a]} Five equivalents of IMP were used to activate tosylhydrazone 1;
^{[b]} Degassed o-DCB as solvent;
^{[c]} Yield determined via HPLC;
^{d}The authors isolated intentionally the open cage fulleroid, performing the cycloaddition and N₂ extrusion at 65-70° C. for 22 h. Isomerisation was induced thermally within 2-7 hr [Hummelen, J. C.; Knight, B. W.; Lepeq, F.; Wudl, F.; Yao, J.; Wilkins, C. L., J. Org. Chem. 1995, 60, 532];
^{e} Reported isolated yield of one-pot reaction procedures using sodium methoxide as a base.
^{f} [Wienk, M. M.; Kroon, J. M.; Verhees, W. J. H.; Knol, J.; Hummelen, J. C.; van Hal, P. A.; Janssen, R. A. J., Angew. Chem. Int. Ed. 2003, 42, 3371];
^{g}Isolated yield using 1,2,4-trichlorobenzene as a solvent [He, Y. J.; Chen, H. Y.; Hou, J. H.; Li, Y. F., J. Am. Chem. Soc. 2010, 132, 1377];
^{h}[He, Y.; Zhao, G.; Peng, B.; Li, Y., Adv. Fund Mater. 2010, 20, 3383]

It will be apparent to the skilled artisan that the possible applications of the continuous process of the present invention extend well beyond those specific embodiments hereinbefore described. These applications include a wide range of functionalization chemistries.

### EXAMPLES

The following examples demonstrate the efficacy of the continuous process of the present invention in the preparation of several functionalized fullerenes.

### Experimental Procedures for Examples

A Vapourtec Microreactor consisting in a R2- and a R4-module with four temperature controllable zones was used (see www.vapourtec.co.uk). Perfluoroalkoxy (PFA) or stainless steel (10 mL internal volume) tubing material was used in the reactor setups. The Vapourtec R4-pumping module was operated in the small scale fluid connection mode with manual loaded sample loops. The reactants were channeled into the tube reactor by pumping solvent from a reservoir at 0.1 or 0.2 mL/min (equivalent to residence times of between 50 and 100 min). All reactions were performed either thermally (R4-module, Vapourtec) and/or photochemically (using a halogen lamp), in o-dichlorobenzene (o-DCB), at concentration ranging from 22 to 28 mM (based on fullerene component) and under approximately 6-19 bar system pressure.

¹H-NMR measurements were carried out from CDCl₃ solutions on a Varian lnova-400 (400 MHz) or a Varian lnova-500 (500 MHz) instrument. HPLC-Analysis was carried out using a Gilson 712 HPLC system, consisting of a Gilson 118 UV/Vis detector, Gilson 307 and 303 pumps. The product ratios and yields are based on the peak integrations of the HPLC trace (detection at 330 and 313 nm). Silica gel (Merck 9385 Kieselgel 60) was used for flash chromatography. Thin layer chromatography was performed on Merck Kieselgel 60 silica gel on glass (0.25 mm thick).

### Small Scale Synthesis of PC₆₁BM

A degassed homogeneous solution of C₆₀ (40 mg, 5.5×10⁻² mmol), p-tosylhydrazone of methyl benzoylbutyrate (21 mg, 1 equiv.) and tetramethylpiperidine (50 μL, 0.3 mmol) in 2 mL o-DCB was pumped through a preheated reactor (at 135° C., 150° C. or 180° C.) using a HPLC pump at the corresponding flow rate. A backpressure regulator (75 psi) was connected to the outflow. An analytical sample diluted with toluene, washed with water, dried with magnesium sulfate and the yield determined by analytical HPLC.

### Large Scale Synthesis of PC₆₁BM

A premixed homogeneous solution containing C₆₀ (6 g, 8.3 mmol), p-tosylhydrazone of methyl benzoylbutyrate (3.18 g, 1 equiv.) and tetramethylpiperidine (5.7 mL, 34 mmol) in 360 mL o-DCB was pumped through a preheated reactor at 70° C. (10 mL internal volume reactor), followed by a 150° C. (20 mL internal volume reactor) and a 250° C. (10 mL reactor volume) temperature sector using a HPLC pump at 1 mL/min flow rate. A backpressure regulator (250 psi) was connected to the outflow. The product was purified by column chromathography using toluene as eluent to give 2.6 g (2.9 mmol, 35%) of PC₆₁BM.

HPLC (min., detection at 330 nm, 100% toluene, 1 mL/min) PC₆₁BM: 7.5 ¹H-NMR (CDCl₃, 500 MHz) δ ppm: 7.94 (d, 2 H, J=8 Hz), 7.56 (t, 2 H, J=7.5 Hz), 7.48 (t, 1 H, J=7.4 Hz), 3.69 (s, 3 H), 2.92 (m, 2 H), 2.54 (t, 2 H, J=7.4 Hz), 2.2 (m, 2 H).

### Synthesis of PC₇₁BM

A degassed solution of C₇₀ (40 mg, 4.8×10⁻² mmol), p-tosylhydrazone of methyl benzoylbutyrate (20 mg, 1.1 equiv.) and tetramethylpiperidine (40 μL, 0.2 mmol) in 2 mL o-DCB was pumped through a tube reactor using a HPLC pump at the corresponding flow rates and irradiated with a white halogen lamp. An analytical sample was diluted with toluene, washed with water dried with magnesium sulfate and the yield determined by analytical HPLC. HPLC (min., 330 nm, 100% toluene, 1 mL/min) PC₇₁BM: 6.5

¹H-NMR (CDCl₃, 500 MHz) [symbol] ppm: 7.2-7.95 (m, 5 H); 3.52, 3.69 (major isomer), 3.76 (s, 3H, ratio 1:10:1); 2.41-2.94 (m, 4 H); 1.79-2.24 (m, 2 H). ¹³C-NMR (CDCl₃, 500 MHz) [symbol] ppm: 173.3, 156.0, 155.3, 152-138 (forest of peaks belonging to sp² carbons on the fullerene cage), 131.6, 130.8, 128.6, 128.3, 72.9, 69.9, 51.8, 36.0, 34.2, 33.9, 21.8.

### Synthesis of IC₆₀BA

A degassed solution of C₆₀ (40 mg, 5.5×10⁻² mmol) and indene (130 μL, 1.1 mmol, 20 equiv.) in 2 mL o-DCB was pumped through a preheated reactor (220° C.) at 100 μL/min. An analytical sample was diluted with toluene/hexane (1:10) and the yield determined by analytical HPLC. After precipitation from ethanol, 40 mg of crude product was purified by column chromatography (30% toluene in hexane).

HPLC (min, 313 nm, toluene/hexane (1:10) 1 mL/min)1C₆₀BA: 16-20 ¹H-NMR (CDCl₃, 500 MHz) δ ppm: 7.91-7.20 (m, 8H), 2.57-4.44 (m, 4H), 48.08-3.22 (m, 2H), 3.06-2.49 (m, 2H). ¹³C-NMR (CDCl₃, 500 MHz) δ ppm: 161-136 (forest of peaks belonging to sp² carbons on the fullerene cage), 127, 124 (sp² carbons on the indene addend), 74, 57, 46 (sp³ on the indene addend).

### Synthesis of IC₇₀BA

C₇₀ (40 mg, 4.7×10⁻² mmol) and indene (200 μL, 36 equiv.) were reacted following the procedure described for IC₆₀BA.

HPLC (min, 313 nm, toluene/hexane (1:10) 1 mL/min) IC₇₀BA: 30-49 ¹H-NMR (CDCl₃, 500 MHz) δ ppm: 7.73-7.24 (m, 8H), 4.79-4.45 (m, 2H), 4.33-4.14 (m, 2H), 2.92-2.70 (m, 2H), 2.50-2.37 (m, 2H). ¹³C-NMR (CDCl₃, 400 MHz) δ ppm: 162-129 (forest of peaks belonging to sp² carbons on the fullerene cage), 127, 124 (sp² carbons on the indene addend), 68.2, 67.4, 58.0, 55.9, 46, 38.7 (sp³ on the indene addend).

1. A continuous process for the functionalization of fullerenes or carbon nanotubes comprising one or more process steps wherein the process steps are conducted substantially in the liquid phase.

2. A process according to claim 1 wherein at least one process step is conducted at a temperature above 25° C.

3. A process according to claim 1 wherein the functionalization comprises a chemical reaction selected from the group consisting of cyclopropanations, cycloadditions, organometallic additions or combinations thereof.

4. A process according to claim 3 wherein the functionalization comprises a chemical reaction selected from the group consisting of 1,3-dipolar cycloadditions, Diels-Alder [2+4] cycloadditions, Grignard additions or combinations thereof.

5. A process according to claim 4 wherein the product of the Grignard addition is subsequently alkylated.

6. A process according to claim 1 wherein the process comprises at least two reaction steps performed at different reaction temperatures.

7. A process according to claim 1 wherein at least one reaction step is performed at more than one temperature.

8. A process according to claim 1 wherein the process is automated using at least one process control system.

9. A process according to claim 1 wherein the process is performed in a tubular reactor, a continuous stirred tank reactor or combinations thereof.

10. A process according to claim 1 wherein the process comprises at least one thermal or photochemical isomerisation.

11. A process according to claim 1 wherein two or more reactants are premixed in a solvent prior to introduction into one or more reactors of the process.

12. A process according to claim 3 wherein the functionalization comprises an in situ deprotonation and diazo compound generation using a soluble organic base.

13. A process according to claim 12 wherein an excess of soluble organic base relative to a diazo compound precursor is utilised.

14. A process according to claim 12 wherein the soluble base is a cyclic or hindered amine derivative or mixtures thereof.

15. A process according to claim 1 wherein the solvent is an aromatic aprotic solvent.

16. A process according to 1 wherein one or more steps are conducted under superheated conditions.

17. A process according to claim 1 wherein one or more steps are conducted under pressures greater than atmospheric pressure.

18. (canceled)

19. A functionalised fullerene or carbon nanotube prepared by the process according to claim 1.

20. A method of using the functionalised fullerene or carbon nanotube of claim 19 in a hetero junction device.

21. A hetero-junction device comprising one or more functionalised fullerenes or carbon nanotubes of claim 19.
